(19) United States
(12) Patent Application Publication
(10) Pub. No.: US 2008/0096395 A1
(43) Pub. Date: Apr. 24, 2008

(54) Producing Method of Semiconductor Device

(76) Inventors: Tadashi Terasaki, Umizu-shi Toyama (JP); Unryu Ogawa, Toyama (JP); Masanori Nakayama, Toyama (JP)

Correspondence Address: BIRCH STEWART KOLASCH & BIRCH, PO BOX 747, FALLS CHURCH, VA, 22040-0747, US

(21) Appl. No.: 10/594,739

(22) PCT Filed: Jul. 27, 2005
(86) PCT No.: PCT/JP05/13733

§ 371 Date: Aug. 22, 2007

(30) Foreign Application Priority Data
Aug. 31, 2004 (JP) 2004-252138
Apr. 5, 2005 (JP) 2005-108645

(51) Int. Cl. H01L 21/31

(52) U.S. Cl. 438/759; 257/E21.211

(57) ABSTRACT

Disclosed is a producing method of a semiconductor device comprising: film thinning a silicon oxide film by heating the silicon oxide film formed after a surface of a silicon substrate is etched by chemical liquid, and one of thermal oxidizing by heating the thinned silicon oxide film to oxidize the silicon oxide film by gas including at least oxygen, and plasma oxidizing the thinned silicon oxide film by plasma discharged gas including at least oxygen.

### TECHNICAL FIELD

The present invention relates to a producing method of a semiconductor device, and more particularly, to a producing method of a semiconductor device having a step of forming a silicon oxide film for a gate insulation film.

### BACKGROUND ART

Conventionally, when a silicon oxide film for a gate insulation film is to be formed, RCA cleaning is carried out as pre-cleaning processing and then, the silicon oxide film is formed.

The RCA cleaning is a cleaning method in which SC-1 (NH₄OH, H₂O₂, H₂O mixture liquid), SC-2 (HCl, H₂O₂, H₂O mixture liquid), dilute fluoric acid, and SPM (H₂SO₄, H₂O₂) cleaning sequences are combined to remove foreign matters, organic matters and metal contaminants. Since the silicon oxide film is formed of H₂O₂, a chemical oxide film of about 10 Å is formed after the processing is completed. With the thinning tendency of the gate insulation films, in order to enhance the transistor characteristics, the existence of the chemical oxide film of about 10 Å can not be ignored, but the film quality of the chemical silicon oxide film is inferior to that of an oxide film formed by high temperature thermal processing. As a result, the film quality of the gate insulation film having the silicon oxide film formed thereafter is also inferior, and this prevents the characteristics of the transistor from being enhanced.

Hence, it is a main object of the present invention to provide a producing method of a semiconductor device capable of forming a high quality insulation film on a surface of a silicon substrate.

### DISCLOSURE OF THE INVENTION

According to one aspect of the present invention, there is provided a producing method of a semiconductor device characterized by comprising:

a film thinning step of thinning a silicon oxide film by heating the silicon oxide film formed after a surface of a silicon substrate is etched by chemical liquid, and

a thermal oxidizing step of heating the thinned silicon oxide film to oxidize the silicon oxide film by gas including at least oxygen, or a plasma oxidizing step of oxidizing the thinned silicon oxide film by plasma discharged gas including at least oxygen.

### BRIEF DESCRIPTION OF THE FIGURES IN THE DRAWINGS

FIG. 1 is a processing flow of a preferred embodiment of the present invention.

FIG. 2 is a diagram used for explaining a producing processing of a thin oxide film according to a preferred embodiment of the invention, and shows processing time dependence of oxide film formation after high temperature annealing.

FIG. 3 is a diagram showing a relation between a nitrogen dose amount in a gate insulation film and leak current of the gate insulation film.

FIG. 4 is a diagram showing On current characteristics enhancing result of a MOS transistor by a thin film high quality oxide film in a preferred embodiment of the invention.

FIG. 5 is a schematic sectional view of a processing apparatus which is suitably used in a preferred embodiment of the invention.

### PREFERABLE MODE FOR CARRYING OUT THE INVENTION

According to a preferable aspect of the present invention, there is provided a producing method of a semiconductor device characterized by comprising:

a film thinning step of thinning a silicon oxide film by heating the silicon oxide film formed after a surface of a silicon substrate is etched by chemical liquid, and

a thermal oxidizing step of heating the thinned silicon oxide film to oxidize the silicon oxide film by gas including at least oxygen, or a plasma oxidizing step of oxidizing the thinned silicon oxide film by plasma discharged gas including at least oxygen.

Although the silicon oxide film formed by chemical liquid has poor film quality, the film quality is enhanced by the thermal processing, and electric characteristics can be enhanced.

By thermally oxidizing or plasma oxidizing the silicon oxide film, roughness of a surface of the film is moderated and flatness of the surface is improved.

That is, if a silicon oxide film (e.g., 11 Å) formed by chemical liquid is thermally processed, the film is more closely grained or packed, or sublimated and thus, the film is thinned (e.g., 4 Å). Then, the silicon oxide film is thermally oxidized or plasma oxidized to thicken the silicon oxide film and obtain a predetermined film thickness (e.g., 8 Å). It is difficult to control the film thickness when a silicon oxide film is thinned by forming processing or thermal processing of the silicon oxide film by chemical liquid cleaning. Therefore, the film thickness is once reduced thinner than a predetermined film thickness and then, an oxide film is added and the film thickness is controlled. With this, it is possible to control a thickness of an extremely thin silicon oxide film.

If a silicon oxide film after its thickness is reduced by thermal processing is thermally oxidized or plasma oxidized, the roughness of the oxide film surface can be moderated. That is, since a distance between a concave portion of the oxide film and a base substrate is shorter than a distance between a convex portion of the oxide film and the base substrate, the concave portion is easily thermally oxidized or plasma oxidized, the film thickness of the concave portion is prone to be thicker than that of the convex portion and as a result, the roughness is moderated.

In a design rule of 65 nm or lower, it is necessary to further reduce a thickness of a gate insulation film, and the present invention in which a film quality is enhanced and roughness can be moderated becomes further effective.

Preferably, in the film thinning step, the silicon oxide film formed after the etching is carried out is processed at 800° C. or higher.

The following conditions are preferable for thinning a film by thermal processing: temperature is in a range of 800° C. to 1000° C., pressure is in a range of 266 to 2660 Pa, a gas flow rate is N₂: 500 to 5000 sccm, and time is 5 to 60 seconds.

The following conditions are preferable for thermal oxidizing processing after the thermal processing: temperature is in a range of 700 to 800° C., pressure is in a range of 266 to 2660 Pa, a gas flow rate is O_{2 :1}-2 slm, H₂ : 100 to 500 sccm, N₂ : O-2O slm, and time is 1 to 30 minutes.

The following conditions are preferable for plasma oxidizing processing after the thermal processing: temperature is in a range of 400 to 900° C., pressure is in a range of 10 to 200 Pa, high frequency electricity is in a range of 50 to 300W, a gas flow rate is O₂: 300 to 1000 sccm, and time is 3 to 240 seconds.

Preferably, the producing method further comprises a silicon oxynitride film forming step in which a silicon oxide film formed by the thermal oxidizing processing or the plasma oxidizing processing is nitrided by plasma including nitrogen to form a silicon oxynitride film.

The following conditions are preferable for plasma nitriding processing: temperature is in a range of 400 to 800° C., pressure is in a range of 10 to 150 Pa, high frequency electricity is in a range of 150 to 300W, a gas flow rate is N₂ 300 to 1000 sccm, and time is 60 to 240 seconds.

Preferably, the thinned silicon oxide film and the silicon oxide film formed by the thermal oxidization or plasma oxidization constitute a portion or all of the gate insulation film.

Preferably, the silicon oxynitride film also constitutes a portion of the gate insulation film.

Preferably, a processing atmosphere in a processing chamber in which the silicon oxide film is heated and thinned is a reduced pressure state. In the reduced pressure state, oxidization does not proceed.

Preferably, in the step for heating and thinning the silicon oxide film, at least one of N₂, Hₑ, Ne, Ar, Kr and Xe is supplied.

Preferably, the chemical liquid is oxygenate mixture liquid.

Preferably, a dose amount of nitrogen of the silicon oxynitride film is 1E15 ( 1×10¹⁵) [atoms/cm²] or higher.

Here, the dose amount is an ion implantation amount per unit area, and is an amount determined by the following equation: (density of the silicon oxynitride film)×(nitrogen concentration) x (film thickness).

The density of the silicon oxynitride film is the number of all atoms of oxygen, nitrogen and silicon per unit volume.

The nitrogen concentration is a value obtained by the following equation: ((the number of atoms of nitrogen per unit volume)/(the number of all atoms of oxygen, nitrogen and silicon per unit volume)).

The film thickness means the entire silicon oxynitride film, and is a thickness from a surface of a base silicon substrate to a surface of the silicon oxynitride film formed on the silicon substrate.

It seems to be an excellent idea to thermally process and remove a silicon oxide film formed by chemical liquid, but in order to do this, it is necessary to highly evacuate to a level as high as about 1×10⁻⁹ Torr. There is also a problem that roughness of a surface of a substrate after natural oxide film is removed is increased.

According to the method of the invention, since it is only required to adjust the pressure in the range of 226 to 2660 Processing apparatus, a vacuum pump capable of evacuating to a level of about 1×10⁻⁴ Torr, it is unnecessary to enhance the performance of the vacuum pump for evacuation to achieve higher vacuum, and a manufacturing cost of such an apparatus is not required. It is possible to further moderate roughness of a surface of a silicon oxide film.

In a preferred embodiment of the invention, when a gate insulation film including a silicon oxynitride film of a semiconductor device is to be formed, a thin oxide film of 7 to 12 Å is subjected to anneal processing of 800° C. or higher in a reduced pressure gas atmosphere and then, nitriding processing is carried out such that a nitrogen dose amount in the silicon oxynitride film after the nitriding processing becomes 1E15 (1×10¹⁵) [atoms/cm²] or higher by a plasma producing apparatus.

After the anneal processing, an oxide film is again formed and then, the nitriding processing is carried out by the plasma producing apparatus.

The thin oxide film of 7 to 12 Å is a chemically oxidized film formed by oxygenate mixture liquid.

The temperature of the anneal processing is 800° C. or higher, the main ingredient of the atmospheric gas is one of or a combination of any of N₂, He, Ne, Ar, Kr and Xe.

Next, a preferred embodiment of the present invention will be explained with reference to the drawings.

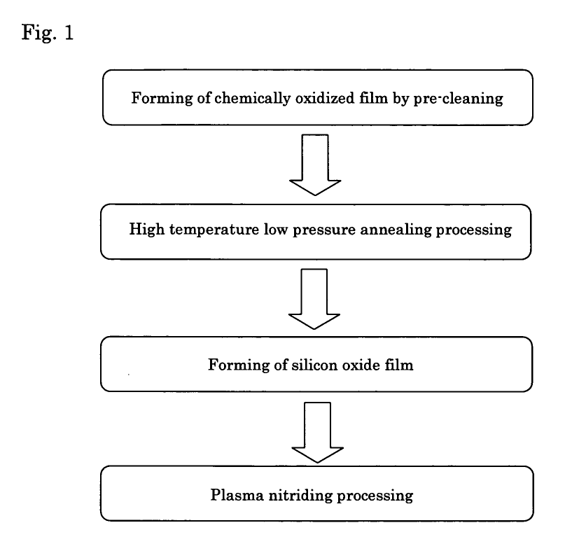

FIG. 1 shows a flow of processing of the preferred embodiment of the invention. When a gate insulation film is to be formed, a surface of a silicon substrate is cleaned by chemical liquid as a pre-step. By the cleaning method called normal RCA cleaning, foreign matters, organic matters and metal contaminants are removed, and a thin oxide film of about 10 Å is formed on a surface and a terminal processing of the surface is carried out in its final step, thereby preventing impurities from being mixed in the surface of the film. However, the film quality of the chemically formed oxide film is inferior to that of an oxide film formed by the high temperature thermal processing, and in order to enhance the characteristics with the thinning tendency of the gate insulation film, existence of a chemical oxide film of about 10 Å can not be ignored.

Hence, in this embodiment, in order to form a high quality thin oxide film, the chemical oxide film of about 10 Å is subjected to the anneal processing, thereby enhancing the quality by the more closely grained or packed effect of the film and thinning the film by the sublimation. The anneal processing is carried out under 1330 Pa, at 1000° C., in nitrogen atmosphere for about 10 seconds. Under the anneal condition, the chemical oxide film of about 10 Å is thinned to about 4 Å.

Since the base oxide film of 4 Å is too thin as a current gate silicon oxynitride film, a high quality oxide film is formed such that the thickness becomes equal to 8 to 12 Å.

In order to form this oxide film, processing (thermal oxidization processing) for about 10 seconds is carried out under 1330 Pa, at 850° C., in an oxygen atmosphere diluted with nitrogen by a high temperature thermal processing apparatus. Further, there is another method (plasma oxidization processing) in which oxygen is activated by a plasma producing apparatus, processing of about 30 seconds is carried out at 400° C., under 100 Pa, with RF power of 150W, and an oxide film is formed.

Next, the oxide film is subjected to the nitriding processing by the plasma producing apparatus, thereby forming an oxynitride film.

Under a nitriding processing condition of nitrogen of 1500 sccm, 5 Pa, 400° C. and RF power of 150W, processing of about 15 seconds is carried out.

At that time, in order to suppress the shift of Vth (threshold voltage) by dispersion of B (boron) in a PMOS transistor, and to reduce leak current, the nitriding processing is carried out such that the dose amount of nitrogen in the oxynitride film becomes 1E15(1×10¹⁵) [atoms/cm²] or higher. It is preferable that the does amount of nitrogen is 1E16(1×10¹⁶) [atoms/cm²] or lower.

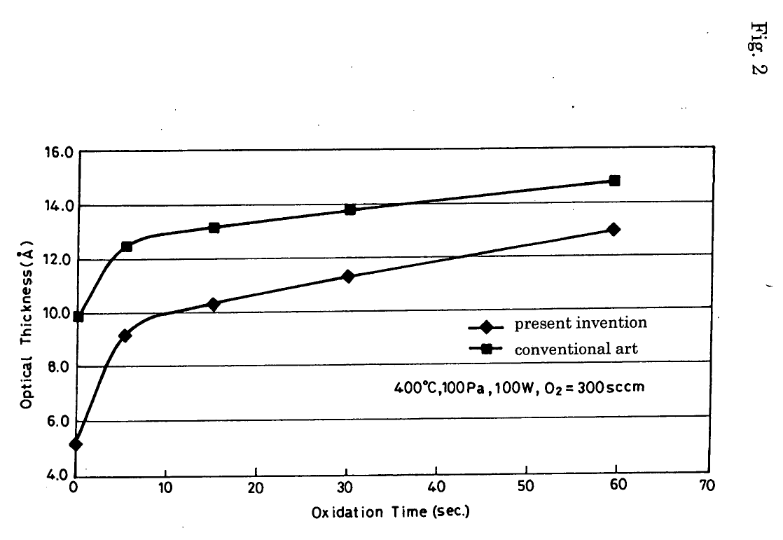

FIG. 2 shows a producing example of a thin oxide film according to a preferred embodiment of the invention. FIG. 2 shows processing time dependence of oxide film formation (plasma oxidization processing) after high temperature anneal. By carrying out the high temperature anneal, the thickness of the oxide film is reduced. It is conceived that this is because a chemical oxide film is more closely grained or packed or sublimated but after that, a high quality thin oxide film can be formed by high temperature thermal processing or plasma processing.

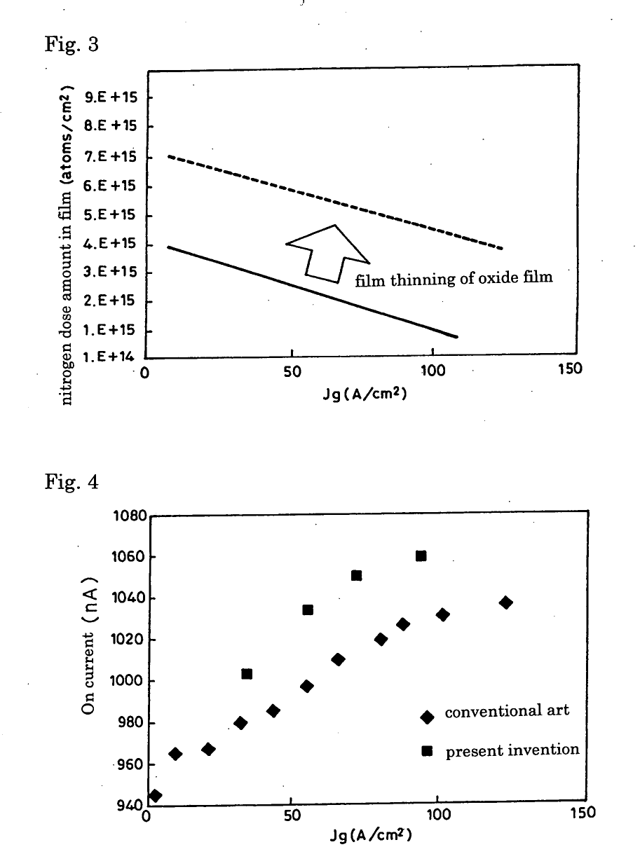

Suppression of a threshold voltage shift of a PMOS transistor and suppression of leak current are carried out for bringing nitrogen into the oxide film. FIG. 3 shows a relation between a nitrogen dose amount in a gate insulation film and leak current of the gate insulation film. In FIG. 3, a lateral axis shows leak current density (Jg (A/cm²)) of a gate insulation film, and a vertical axis shows a dose amount (atoms/cm²) of nitrogen in the film. This is an example in which the oxide film is 12 Å, but in order to achieve the above object with respect to the requirement of thinning the film, it can be found that the necessity for enhancing the nitrogen concentration is increased.

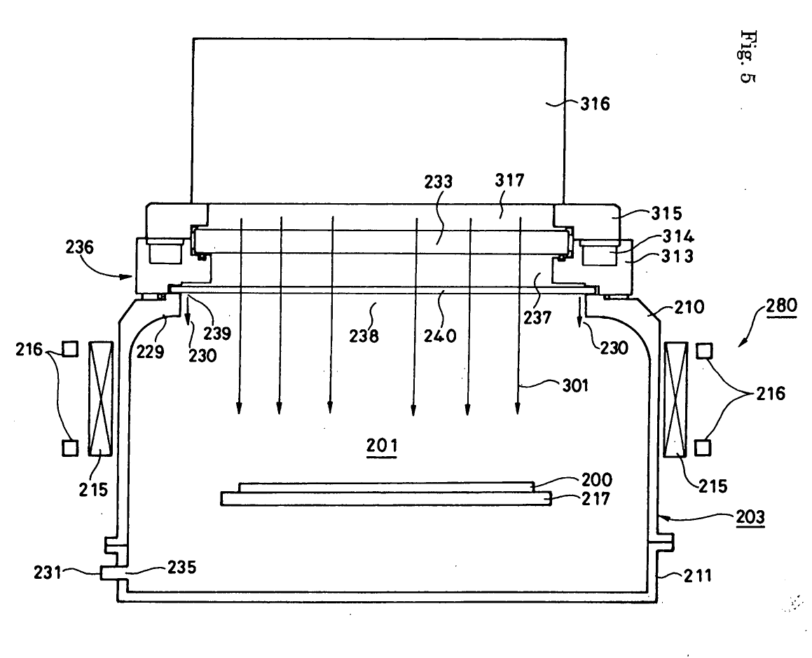

As an example in which an oxynitride film is applied to a MOS transistor and characteristics are compared and evaluated, FIG. 4 shows On current characteristics enhancing result of the MOS transistor by a thin high quality oxide film according to the embodiment. In FIG. 4, a lateral axis shows leak current density (Jg (A/cm²)) of a gate insulation film, and a vertical axis shows On current (nA). It can be found that if a thin oxide film having small leak current is formed in this embodiment, On current can be enhanced.

As explained above, if a gate silicon oxynitride film of the preferred embodiment of the invention is formed, it is possible to form a thin oxynitride film having small leak current, and to enhance the characteristics of the MOS transistor.

Next, a plasma processing apparatus which is suitably used in the preferred embodiment of the invention will be explained with reference to FIG. 5.

This plasma processing apparatus is a substrate processing apparatus (MMT apparatus, hereinafter) which plasma-processes a substrate such as a wafer using a deformed magnetron type plasma source which can produce high density plasma by an electric field and a magnetic field. According to this MMT apparatus, a substrate is disposed in a processing chamber having air tightness, reaction gas is introduced into the processing chamber through a shower plate, the pressure in the processing chamber is maintained at a given value, high frequency electricity is supplied to a discharging electrode to form the electric field, the magnetic field is applied to cause magnetron discharge. Electrons near a discharge electrode orbit while drifting and keeping cycloid motion, and the electrons are captured by the magnetic field. Therefore, ionization generation rate becomes high, and high density plasma can be produced. Reaction gas is excited and decomposed by the high density plasma. By the excited and decomposed reaction gas, various plasma processing can be carried out for substrates such as dispersion processing of oxidizing or nitriding of a surface of a substrate, formation of a thin film on a surface of a substrate, and etching of a surface of a substrate.

A substrate in the processing chamber can be heated by light from a light source.

The MMT apparatus includes a processing container 203 comprising an upper container 210 and a lower container 211. The lower container 211 and the upper container 210 which is put on the lower container 211 constitute a processing chamber 201 which processes a wafer 200 therein. The upper container 210 is formed into a domical shape made of dielectric of aluminum nitride, aluminum oxide or quartz. The lower container 211 is made of aluminum.

The upper container 210 is provided at its upper portion with a shower head 236. A gas introducing port (not shown) for introducing reaction gas is in communication with the shower head 236. The shower head is provided at its lower portion with gas jet openings 239 which are jet holes from which gas is injected into the processing chamber 201.

The shower head 236 includes a sidewall member 313, a lid 233, a shielding plate 240, a buffer chamber 237, an opening 238 and the gas jet openings 239.

The buffer chamber 237 is provided as a gas dispersion space through which gas is introduced into an upper portion of the processing chamber 201. The buffer chamber 237 includes the sidewall member 313, the lid 233, the opening peripheral portion 229 and the shielding plate 240 covering the opening 238. Since the shielding plate 240 is provided in the buffer chamber 237, the gas dispersion space is formed between the lid 233 and the shielding plate 240. The lid 233 and the shielding plate 240 are made of quartz.

The opening 238 is formed in a ceiling of the processing chamber 201 opposed to a main surface of the wafer 200. The buffer chamber 237 and the processing chamber 201 are in communication with each other.

The shielding plate 240 covers the opening 238 from an inner side of the buffer chamber 237 and gas introduced into the buffer chamber 237 flows into the opening peripheral portion 229.

The gas jet openings 239 are provided in a gap formed between an outer periphery of a lower surface of the shielding plate 240 and a peripheral portion of the opening 238. The gas jet openings 239 are formed inside of the buffer chamber 237 on a deep side from an opening surface of the opening 238 so that the gas jet openings 239 are not exposed to the processing chamber 201 which is exposed to plasma. The plurality of gas jet openings 239 are formed at equal distances from one another in the circumferential direction of the opening 238. The gas jet openings 239 inject gas flowing to the opening peripheral portion 229 by the shielding plate 240 into the processing chamber 201 in a form of shower.

A gas discharge port 235 which is a discharge port through which gas is discharged is formed in a sidewall of the lower container 211 such that reaction gas 230 is supplied from the shower head 236 to the processing chamber 201 and gas after processing of a substrate flows toward a bottom of the processing chamber 201 from peripheries of a susceptor 217. The gas discharge port 235 is connected to the gas discharge pipe 231.

Plasma producing means 280 forms a plasma producing region in the processing chamber 201. The plasma producing means 280 includes discharging means which excites the supplied reaction gas, and magnetic field forming means which traps electrons.

The discharge means includes a cylindrical electrode 215, a matching device (not shown) and a high frequency power supply (not shown). The magnetic field forming means includes cylindrical magnets 216.

The cylindrical electrode 215 has a cylindrical cross section, and preferably comprises a cylindrical electrode. The cylindrical electrode 215 is disposed on an outer periphery of the processing chamber 201, and surrounds the plasma producing region near the cylindrical electrode 215 in the processing chamber 201. A high frequency power supply (not shown) which applies high frequency electricity is connected to the cylindrical electrode 215 through a matching device (not shown) which matches impedance.

Each of the cylindrical magnets 216 has a cylindrical cross section, and comprises a cylindrical permanent magnet. The material of the permanent magnet is neodymium rare-earth cobalt magnet for example. The cylindrical magnets 216 are disposed near upper end lower two ends of an outer surface of the cylindrical electrode 215 in an axial direction of the cylinder. The upper and lower cylindrical magnets 216 and 216 are provided at their both ends (inner peripheral ends and outer peripheral ends) along a radial direction of the processing chamber 201 with magnetic poles, and directions of the magnetic poles of the upper and lower cylindrical magnets 216 and 216 are opposite from each other. Therefore, the magnetic poles of the inner peripheral portions are different from each other. With this, magnetic lines of force are formed in the axial direction of the cylinder along the inner peripheral surface of the cylindrical electrode 215.

The susceptor 217 as substrate holding means for holding the substrate 200 is disposed on a central portion of a bottom of the processing chamber 201. The susceptor 217 can heat the wafer 200. A heater (not shown) as heating means is integrally embedded in the susceptor 217.

The shower head 236 is provided at its upper portion with a light source 316. The light source 316 is mounted on the sidewall member 313 by a light source peripheral member 315. An opening 317 is formed in a central portion of the light source peripheral member 315. The sidewall member is provided with a cooling water passage 314. Cooling water flows so that heat is not added to the light source peripheral member 315. As a material of the light source peripheral member 315 which comes into contact with the light source 316, a material having high thermal conductivity such as aluminum is used. Heat and light are concentrated around the light source. Therefore, it is possible to lower the temperature rise of the light source peripheral member 315 by flowing cooling water to such a local portion.

The substrate 200 is irradiated with light 301 from the light source through the opening 317, the lid 233 made of quartz, the reaction gas shielding plate 240 made of quartz and the opening 238, and the substrate 200 can be heated and processed.

By this apparatus, the heating processing (anneal) step, the thermal oxidation step or the plasma oxidation step and the plasma nitriding step can continuously be carried out.

The heating processing (anneal) step, the thermal oxidation step may be carried out by a lamp heating apparatus using a lamp only, and the plasma oxidation step and the plasma nitriding step may be carried out by the MMT apparatus having only a discharge electrode without lamp.

The entire disclosures of Japanese Patent Application No. 2004-252138 filed on Aug. 31, 2004 and Japanese Patent Application No. 2005-108645 filed on Apr. 5, 2005 including specifications, claims, drawings and abstracts are incorporated herein by reference in there entireties

Although various exemplary embodiments have been shown and described, the invention is not limited to the embodiments shown. Therefore, the scope of the invention is intended to be limited solely by the scope of the claims that follow.

### INDUSTRIAL APPLICABILITY

According to the one embodiment of the present invention, as explained above, there is provided a producing method of a semiconductor device capable of forming a high quality insulation film on a surface of a silicon substrate, and characteristics of a silicon substrate can be enhanced.

As a result, the present invention can especially preferably be utilized for a method for producing a silicon substrate using a semiconductor device silicon wafer.

1. A producing method of a semiconductor device, characterized by comprising:
a film thinning a silicon oxide film by heating the silicon oxide film formed after a surface of a silicon substrate is etched by chemical liquid, and
one of thermal oxidizing by heating the thinned silicon oxide film to oxidize the silicon oxide film by gas including at least oxygen, or a and plasma oxidizing the thinned silicon oxide film by plasma discharged gas including at least oxygen.

2. A producing method of a semiconductor device as recited in claim 1, wherein
in the film thinning step, the silicon oxide film formed after the etching is carried out is processed at 800° C. or higher.

3. A producing method of a semiconductor device as recited in claim 2, wherein
in the film thinning step, the silicon oxide film formed after the etching is carried out is processed at 800° C. to 1000° C.

4. A producing method of a semiconductor device as recited in any one of claims 1 to 3, wherein
in the film thinning se, the silicon oxide film formed after the etching is carried out is processed under a reduced pressure.

5. A producing method of a semiconductor device as recited in claim 4, wherein
the reduced pressure is 266 Pa to 2660 Pa.

6. A producing method of a semiconductor device as recited in claim 4, wherein
in the film thinning step, the silicon oxide film formed after the etching is carried out is processed by nitrogen.

7. A producing method of a semiconductor device as recited in claim 6, wherein
in the film thinning step, the silicon oxide film formed after the etching is carried out is processed for 5 seconds to 60 seconds.

8. A producing method of a semiconductor device as recited in any one of claims 1 to 3, further comprising:
plasma nitriding the silicon oxide film by plasma discharged gas including at least nitrogen to form a silicon oxynitride film, wherein
a dose amount of nitrogen of the silicon oxynitride film is made to be 1×10¹⁵ [atoms/cm²] or
higher by the plasma nitriding so.
